(19) United States
(12) Patent Application Publication
(10) Pub. No.: US 2026/0163560 A1
(43) Pub. Date: Jun. 11, 2026

(54) ELECTRONIC DEVICE HAVING RETIMED PIPELINE DESIGN

(71) Applicant: Realtek Semiconductor Corp., HsinChu (TW)

(72) Inventors: Jeong-Fa Sheu, HsinChu (TW); Mei-Chuan Lu, HsinChu (TW); Jui-Chang Tsao, HsinChu (TW); Yung-Chang Lin, HsinChu (TW)

(73) Assignee: Realtek Semiconductor Corp., HsinChu (TW)

(21) Appl. No.: 19/387,497

(22) Filed: Nov. 12, 2025

(30) Foreign Application Priority Data
Dec. 5, 2024 (TW) 113147211

(51) Int. Cl. H03K 3/037; H03K 5/135

(52) U.S. Cl. CPC H03K 3/037; H03K 5/135

(57) ABSTRACT

The present invention provides an electronic device including a first circuit module, a second circuit module and a transmission module is disclosed. The transmission module is coupled between the first circuit module and the second circuit module, wherein the first circuit module transmits multiple data to the second circuit module through the transmission module, and the transmission module includes at least one stage of driving circuits. Each stage of driving circuit includes multiple retimed pipeline flip-flops, and during clock tree synthesis, only the flip-flops within each stage of the driving circuit are clock balanced, and if there are multiple stages of driving circuits, no clock balance is performed between the multiple stages of driving circuits.

### BACKGROUND OF THE INVENTION

### 1. Field of the Invention

The present invention relates to two circuit modules with long-distance signal transmission.

### 2. Description of the Prior Art

Very large-scale integration (VLSI) circuits are typically divided into multiple circuit modules, and each circuit module is designed as a hard macro during the circuit layout process. When some hard macros are located far apart, signals need to be transmitted through long-distance routing. However, when the clock frequency used by the hard macro is high, this long-distance signal transmission may require several to dozens of clock cycles. Therefore, in order to solve the setup time violation issue of flip-flops caused by long-distance signal transmission, it is traditionally required to insert a retimed pipeline flip-flop at appropriate intervals along the long-distance routing to meet the setup time requirements of the flip-flops. The setup time for flip-flops is a well-known technique in this field, and thus will not be described here.

Due to the difficulty of achieving globally-synchronous design in VLSI circuits, one solution is to allow multiple circuit modules within the VLSI circuit to operate without the need for deliberate clock tree balancing to reduce clock skew. Instead, each circuit module handles its own internal clock synchronization, i.e., using a globally-asynchronous and locally-synchronous (GALS) design approach. Additionally, because multiple retimed pipeline flip-flops placed along the routing between two circuit modules require clock balancing, it is generally necessary to generate multiple clock signals from a single clock source through clock tree branches to trigger these retimed pipeline flip-flops. However, when there are many long routes between two circuit modules, the multiple clock signals generated by the clock tree often have significant clock skew, which increases the difficulty of meeting both setup time and hold time requirements across different process corners. This could potentially lead to both setup time violations and hold time violations in different corners.

### SUMMARY OF THE INVENTION

Therefore, one of the objectives of the present invention is to propose an electronic device comprising two circuit modules with long-distance signal transmission, in order to solve the problems described in the prior art.

According to one embodiment of the present invention, an electronic device comprising a first circuit module, a second circuit module and a transmission module is disclosed. The transmission module is coupled between the first circuit module and the second circuit module, wherein the first circuit module transmits multiple data to the second circuit module through the transmission module, and the transmission module comprises at least one stage of driving circuits. Each stage of the at least one stage of driving circuits comprises multiple retimed pipeline flip-flops, and during clock tree synthesis, only the flip-flops within each stage of the at least one stage of the driving circuits are clock balanced, and if there are multiple stages of driving circuits, no clock balance is performed between the at least one stage of driving circuits.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a chip according to an embodiment of the present invention.

FIG. 2 is a schematic diagram of a circuit module and a transmission module according to an embodiment of the present invention.

FIG. 3 is a schematic diagram of a clock tree.

### DETAILED DESCRIPTION

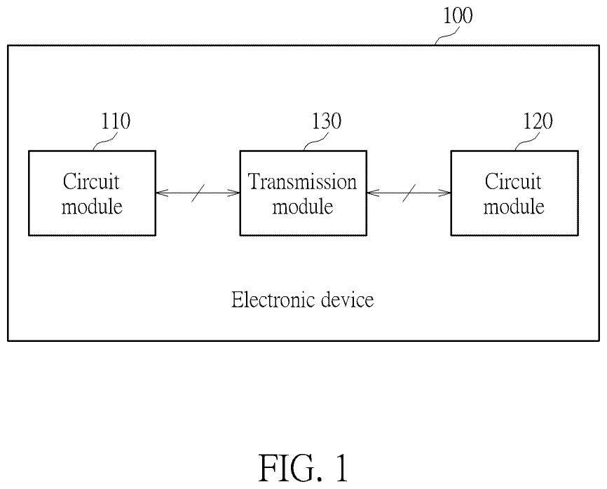

FIG. 1 is a schematic diagram of an electronic device 100 according to an embodiment of the present invention, where the electronic device 100 is a chip. As shown in FIG. 1, the electronic device 100 includes multiple circuit modules (with circuit modules 110 and 120 as examples in this embodiment) and at least one transmission module 130. The transmission module 130 includes multiple routes and associated circuits for signal transmission between circuit modules 110 and 120. The circuit module 110 transmits multiple data to circuit module 120 via the transmission module 130. In this embodiment, the electronic device 100 includes an VLSI circuit, and there is a long distance between circuit modules 110 and 120, meaning that the signal transmission time of the multiple routes in transmission module 130 exceeds one clock cycle of the clock signal used by circuit modules 110 or 120.

In this embodiment, since there is a long distance between circuit modules 110 and 120, the electronic device 100 adopts a globally-asynchronous and locally-synchronous (GALS) circuit design approach to implement circuit modules 110 and 120. That is, the circuit module 110 performs clock tree balancing only for the clock signal(s) used by its internal circuits to reduce clock skew, and the circuit module 120 performs clock tree balancing only for the clock signal(s) used by its internal circuits to reduce clock skew. However, the clock signals used by circuit modules 110 and 120 are not synchronized with each other.

As mentioned in the prior art, when the clock tree is not properly balanced, a chip may encounter setup time violations and hold time violations in the design of long-distance routing. Therefore, this embodiment proposes the transmission module 130, which can reduce the complexity of clock tree balancing and has a smaller chip area and lower power consumption.

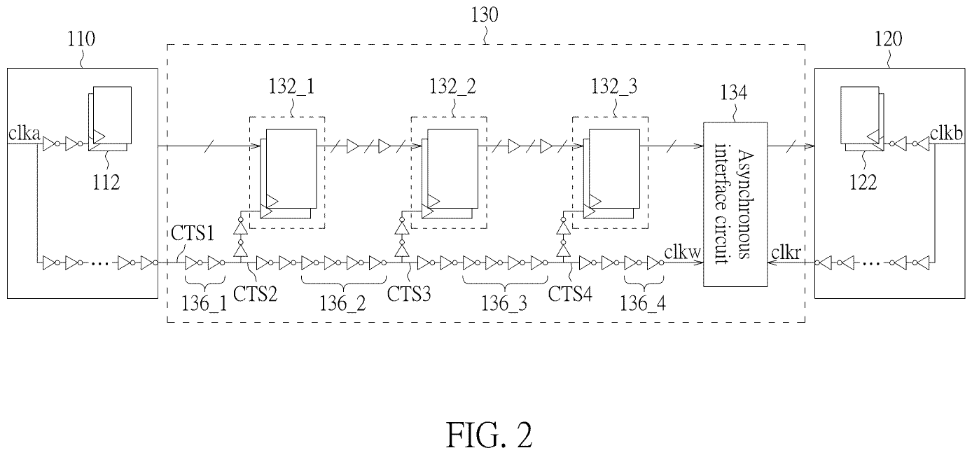

FIG. 2 is a schematic diagram of circuit modules 110 and 120, and transmission module 130 according to an embodiment of the present invention, where circuit module 110 is the transmitting end and circuit module 120 is the receiving end, as explained in the figure. The circuit modules 110 and 120 are each designed as hard macro during the circuit layout process, but the present invention is not limited to this. As shown in FIG. 2, the circuit module 110 includes multiple flip-flops 112 and other logic circuits, with the flip-flops 112 being triggered by a clock signal clka through a clock tree network. The circuit module 120 includes multiple flip-flops 122 and other logic circuits, with the flip-flops 122 being triggered by a clock signal clkb through a clock tree network. The clock signals clka and clkb can be generated from the same clock signal or from different clock signals. The transmission module 130 includes at least one or more stages of driving circuits (in this embodiment, three stages of driving circuits 132_1, 132_2 and 132_3 are used as examples), an asynchronous interface circuit 134, and multiple clock trees (in this embodiment, four clock trees 136_1, 136_2, 136_3 and 136_4 are used as examples). Each stage of the driving circuits 132_1, 132_2 and 132_3 includes multiple retimed pipeline flip-flops. The placement of each driving circuit and the asynchronous interface circuit 134 are spaced apart by an appropriate distance to transmit signals from circuit module 110 to the circuit module 120.

In another embodiment, depending on the distance between circuit modules 110 and 120 and the clock frequency, the number of stages of the driving circuits may be one stage, two stages, or more than three stages.

In another embodiment, the circuit modules 110 and 120 may not be hard macros during the circuit layout process; alternatively, one of them may be a hard macro while the other one is not.

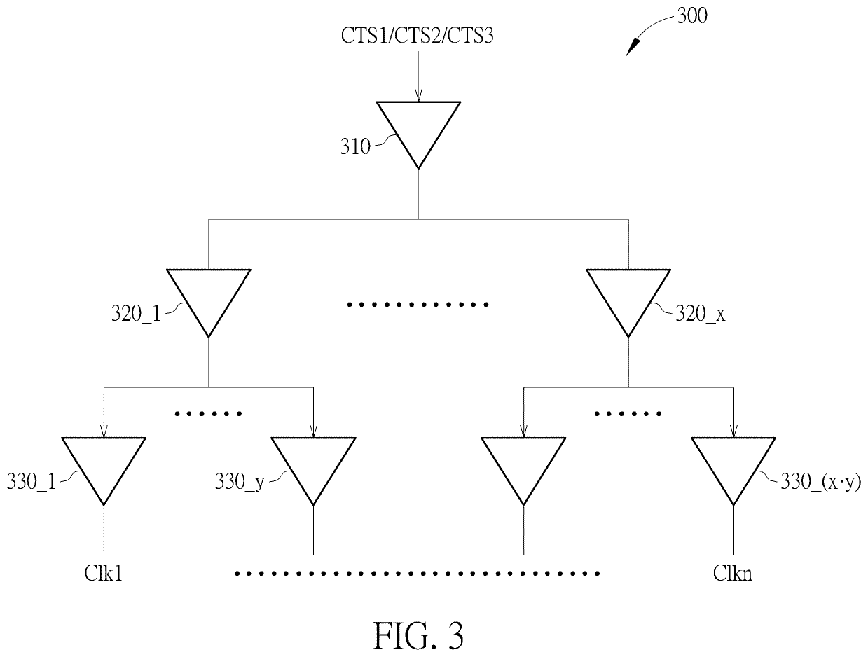

In the operation of circuit modules 110 and 120 and transmission module 130 as shown in FIG. 2, first, the circuit module 110 transmits multiple data simultaneously to the first-stage driving circuit 132_1 of transmission module 130, and generates a specific clock signal CTS1 based on the clock signal clka. The clock tree 136_1 receives the specific clock signal CTS1 to generate clock signals to the transmission module 130 to trigger the multiple retimed pipeline flip-flops in the first-stage driving circuit 132_1. Specifically, referring to the clock tree 300 shown in FIG. 3, which includes multiple stages of buffers, the specific clock signal CTS1 is processed through the first-stage buffer 310, second-stage buffers 320_1-320_x, and third-stage buffers 330_1-330_(x*y) to generate multiple clock signals Clk1-Clkn to trigger the multiple retimed pipeline flip-flops in the first-stage driving circuit 132_1, to send the data to the second-stage driving circuit 132_2. In one embodiment, the clock tree 136_1 generates multiple first clock signals based on the specific clock signal CTS1 to trigger the multiple retimed pipeline flip-flops in the first-stage driving circuit 132_1, while clock tree 136_2 generates multiple second clock signals based on a specific clock signal CTS2 to trigger the multiple retimed pipeline flip-flops in the second-stage driving circuit 132_2, where the specific clock signal CTS2 is generated based on the specific clock signal CTS1. In a first example, the specific clock signal CTS2 is generated by receiving the specific clock signal CTS1 through clock tree 136_1. In a second example, the clock tree 136_1 may be integrated into the clock tree 300 shown in FIG. 3, meaning that clock tree 136_1 could be one of the branches of clock tree 300, and the specific clock signal CTS2 is generated through another branch of clock tree 300 that receives the first specific clock signal CTS1, wherein the other branch of clock tree 300 is different from clock tree 136_1.

Next, after the specific clock signal CTS2 is processed through the branches of clock tree 300, multiple clock signals Clk1-Clkn are generated to trigger the multiple retimed pipeline flip-flops in the second-stage driving circuit 132_2, to send the data to the third-stage driving circuit 132_3. Then, the specific clock signal CTS2 is processed through clock tree 136_2 to generate a specific clock signal CTS3.

Next, after the specific clock signal CTS3 is processed through the branches of clock tree 300, multiple clock signals Clk1-Clkn are generated to trigger the multiple retimed pipeline flip-flops in the third-stage driving circuit 132_3, to send the data to the asynchronous interface circuit 134. Then, the specific clock signal CTS3 is processed through clock tree 136_3 to generate a specific clock signal CTS4.

Next, after the specific clock signal CTS4 is processed through the branch of clock tree 300, multiple clock signals Clk1-Clkn are generated to trigger the asynchronous interface circuit 134. Then, the specific clock signal CTS4 is processed through clock tree 136_4 to generate a write clock signal clkw.

In another embodiment, the multiple stages of buffers in the clock tree 300 shown in FIG. 3 can be implemented by using an even number of inverters, as illustrated by clock trees 136_1, 136_2, 136_3, and 136_4 in FIG. 2. The clock tree design is a well-known technique in the field and is not the focus of the present invention, so it will not be described in detail here.

The circuit module 120 generates a read clock signal clkr based on clock signal clkb to the asynchronous interface circuit 134, and the asynchronous interface circuit 134 uses the write clock signal clkw and the read clock signal clkr to transfer the data received from the third-stage driving circuit 132_3 to the circuit module 120. In one embodiment, the asynchronous interface circuit 134 can be an asynchronous first-in, first-out (FIFO) interface circuit, which is used to convert the data from the third-stage driving circuit 132_3 to a clock domain of the circuit module 120, for use by circuit module 120. Additionally, since the operation and architecture of the asynchronous interface circuit 134 are well-known to those skilled in the art, for example, as referenced in U.S. Patent Application Publication No. US 2004/0170033, the related details will not be described here.

In the embodiment of FIG. 2, the multiple clock signals used in each stage driving circuit 132_1, 132_2 and 132_3 only need to maintain clock balance/clock synchronization (clock propagation delay balance) for itself. In this embodiment, clock balance/clock synchronization means that after a clock signal is synthesized by a clock tree, the propagation delays of the multiple clock signal branches (such as Clk1 . . . Clkn in FIG. 3) are the same or very close. In other words, the phase differences between the multiple clock signals are within a certain range or below a threshold value. For example, the multiple clock signals used to trigger the first-stage driving circuit 132_1 will have the same or very close phase; the multiple clock signals used to trigger the second-stage driving circuit 132_2 will have the same or very close phase; and the multiple clock signals used to trigger the third-stage driving circuit 132_3 will have the same or very close phase. Additionally, clock balance/clock synchronization is not performed between the different stages of the driving circuits 132_1, 132_2, and 132_3, meaning that the clock signals between the different stages are not synchronized or balanced. For example, the multiple retimed pipeline flip-flops of the first-stage driving circuit 132_1 are triggered by multiple first clock signals, the multiple retimed pipeline flip-flops of the second-stage driving circuit 132_2 are triggered by multiple second clock signals, and the multiple retimed pipeline flip-flops of the third-stage driving circuit 132_3 are triggered by multiple third clock signals. The multiple first clock signals and the multiple second clock signals can be clock unbalanced, and the multiple third clock signals can be clock unbalanced with both the multiple first and multiple second clock signals. As a result, the design of the transmission module 130 in clock tree synthesis (CTS) becomes simpler and easier to handle, reducing the complexity of the design. Furthermore, since the multiple retimed pipeline flip-flops in each stage of driving circuits 132_1, 132_2 and 132_3 are generated by branching from the same clock signals CTS1/CTS2/CTS3/CTS4 and do not need to be balanced with the clock signals from other areas of the electronic device 100, it can avoid the significant on-chip variation (OCV) effects between the components on the chip due to long branch wiring in the global clock tree of electronic device 100, as well as issues such as clock tree branch crosstalk interference.

In one embodiment, the data signal transmission delay from each stage of driving circuit in the circuit module 130 to the next stage of driving circuit does not need to be balanced with the corresponding clock tree delay of the next stage of driving circuit. For example, suppose the data signal outputted from the flip-flop of the driving circuit 132_1 is transmitted to the flip-flop of the next stage of driving circuit 132_2, with a delay time of Td12, and the delay time of clock tree 136_2 is Tc12, these two delay times Td12 and Tc12 do not need to be the same or similar, so it will not increase the complexity of the circuit layout design.

On the other hand, through the specific clock tree synthesis design strategy of transmission module 130 shown in FIG. 2, the distance between each stage of the driving circuit 132_1, 132_2 and 132_3 can be increased. As a result, the number of stages of driving circuits required by transmission module 130 can be reduced, which helps to decrease the chip area and power consumption.

Additionally, since the asynchronous interface circuit 134 is used to convert the data from the third-stage driving circuit 132_3 to the clock domain of circuit module 120 for use by circuit module 120, the asynchronous interface circuit 134 needs to be placed closer to circuit module 120 in the electronic device 100, or the asynchronous interface circuit 134 can be positioned within the circuit module 120.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device, comprising:
a first circuit module;
a second circuit module; and
a transmission module, coupled between the first circuit module and the second circuit module, wherein the first circuit module transmits multiple data to the second circuit module through the transmission module, and the transmission module comprises:
at least one stage of driving circuits, wherein each stage of the at least one stage of driving circuits comprises multiple retimed pipeline flip-flops, and during clock tree synthesis, only the flip-flops within each stage of the at least one stage of the driving circuits are clock balanced, and if there are multiple stages of driving circuits, no clock balance is performed between the at least one stage of driving circuits.

2. The electronic device of claim 1, wherein a signal transmission time of the transmission module is greater than one cycle of a clock signal used by the first circuit module.

3. The electronic device of claim 2, wherein a data signal transmission delay from each stage of the at least one stage of driving circuits to a next stage of the at least one stage of driving circuits does not need to be balanced with a clock tree delay of the next stage of the at least one stage of driving circuits.

4. The electronic device of claim 1, wherein the at least one stage of driving circuits comprise a first-stage driving circuit and a second-stage driving circuit, the first-stage driving circuit comprises multiple first retimed pipeline flip-flops, the second-stage driving circuit comprises multiple second retimed pipeline flip-flops; and the multiple first retimed pipeline flip-flops are triggered by multiple first clock signals, the multiple second retimed pipeline flip-flops are triggered by multiple second clock signals, and the multiple first clock signals and the multiple second clock signals are clock unbalanced with respect to each other.

5. The electronic device of claim 4, wherein the transmission module receives a first specific clock signal from the first circuit module, and the transmission module further comprises:
a first clock tree, configured to generate the multiple first clock signals according to the first specific clock signal; and
a second clock tree, configured to generate the multiple second clock signals according to a second specific clock signal, wherein the second specific clock signal is generated according to the first specific clock signal.

6. The electronic device of claim 5, wherein the second specific clock signal is generated by the first clock tree receiving the first specific clock signal.

7. The electronic device of claim 5, wherein the second specific clock signal is generated by another clock tree receiving the first specific clock signal.

8. The electronic device of claim 4, wherein the at least one stage of driving circuits further comprise a third-stage driving circuit, the third-stage driving circuit comprises multiple third retimed pipeline flip-flops, the multiple third retimed pipeline flip-flops are triggered by multiple third clock signals, and the multiple third clock signals are clock unbalanced with respect to the multiple first clock signals and the multiple second clock signals.

9. The electronic device of claim 1, further comprising:
an asynchronous interface circuit, configured to convert the multiple data from a last-stage driving circuit of the at least one stage of driving circuits to a clock domain of the second circuit module for use by the second circuit module.

10. The electronic device of claim 9, wherein the asynchronous interface circuit is located near the second circuit module or is positioned within the second circuit module.
